(19) United States
(12) Patent Application Publication
(10) Pub. No.: US 2026/0369521 A1
(43) Pub. Date: Nov. 19, 2026

(54) Charged Particle Beam Device and Method for Adjusting Charged Particle Beam Device

(71) Applicant: Hitachi High-Tech Corporation, Minato-ku, Tokyo (JP)

(72) Inventors: Haruyuki ISHII, Tokyo (JP); Tatsuya ASAHATA, Tokyo (JP); Atsushi UEMOTO, Tokyo (JP)

(21) Appl. No.: 19/142,673

(22) PCT Filed: Dec. 28, 2022
(86) PCT No.: PCT/JP2022/048547

§ 371 Date: Jun. 24, 2025

(51) Int. Cl. H01J 37/302; H01J 37/28; H01J 37/305

(52) U.S. Cl. CPC H01J 37/3023; H01J 37/28; H01J 37/3056; H01J 2237/31749

(57) ABSTRACT

An adjustment to be executed is appropriately selected and executed at an appropriate timing. In a charged particle beam apparatus for generating an observation image of a sample by irradiating the sample with a charged particle beam, a control unit executes a program to execute processing on the sample (S601), selects an adjustment recipe to be executed from a plurality of adjustment recipes based on an adjustment history of the charged particle beam apparatus or an observation image (S604), determines a timing, at which the adjustment is executed during execution of the program, based on a status of the charged particle beam apparatus and an execution status of the program (S605 to S607), and executes the selected adjustment recipe (S608).

### TECHNICAL FIELD

The present disclosure relates to a charged particle beam apparatus and a method for adjusting the charged particle beam apparatus.

### BACKGROUND ART

A charged particle beam apparatus, such as a scanning electron microscope (SEM) or a focused ion beam (FIB) apparatus, is an apparatus suitable for observation or machining of a semiconductor pattern or the like formed on a semiconductor wafer that is becoming increasingly miniaturized.

In order to execute highly accurate observation and machining using an apparatus such as the SEM or the FIB, an apparatus condition needs to be appropriately adjusted. PTL 1 discloses a charged particle beam apparatus that executes an automatic adjustment such as an axis adjustment for a charged particle beam at an appropriate timing. In the charged particle beam apparatus in PTL 1, it is determined whether the automatic adjustment is necessary at a timing when an optical condition is changed (see S903 in FIG. 9), and the automatic adjustment is executed when, for example, a considerable amount of time has passed from the previous automatic adjustment.

### CITATION LIST

### Patent Literature

PTL 1: JP2017-076523A

### SUMMARY OF INVENTION

### Technical Problem

PTL 1 discloses that the automatic adjustment is executed at the timing when the optical condition is changed or a timing when a measurement point is moved, but a content of the automatic adjustment executed in PTL 1 is fixed. Although various adjustments are necessary depending on an adjustment history of the charged particle beam apparatus and a change in an observation image, in PTL 1, since an adjustment incorporated in a recipe is automatically executed, it is not possible to execute an appropriate adjustment at an appropriate timing.

Therefore, the disclosure provides a charged particle beam apparatus that can appropriately select an adjustment to be executed and execute the adjustment at an appropriate timing.

### Solution to Problem

In order to solve the above-described problem, a charged particle beam apparatus for generating an observation image of a sample by irradiating the sample with a charged particle beam, the charged particle beam apparatus including: a storage unit configured to store a program for executing processing on the sample and a plurality of adjustment recipes for executing an adjustment of an apparatus condition of the charged particle beam apparatus; and a control unit configured to cause the processing on the sample to be executed by executing the program stored in the storage unit and to cause the adjustment of the apparatus condition to be executed by executing the adjustment recipe stored in the storage unit, in which the control unit selects the adjustment recipe to be executed from the plurality of adjustment recipes stored in the storage unit based on an adjustment history of the charged particle beam apparatus or the observation image, and determines a timing, at which the adjustment is executed during execution of the program, based on a status of the charged particle beam apparatus and an execution status of the program to execute the selected adjustment recipe.

### Advantageous Effects of Invention

According to the disclosure, an adjustment to be executed can be appropriately selected and executed at an appropriate timing.

Problems, configurations, and effects other than those described above will be clarified by the following description of an embodiment.

### BRIEF DESCRIPTION OF DRAWINGS

FIG. 1 is a diagram illustrating an overall configuration of a FIB-SEM composite apparatus according to an embodiment.

FIG. 2 is a block diagram illustrating a hardware structure of a control device according to the embodiment.

FIG. 3 is a diagram illustrating a plurality of adjustment recipes and application programs stored in a storage device according to the embodiment.

FIG. 4 is a diagram illustrating an adjustment recipe display screen displayed on a display device according to the embodiment.

FIG. 5 is a diagram illustrating a method of customizing the adjustment recipe according to the embodiment.

FIG. 6 is a flowchart illustrating a method for adjusting the FIB-SEM composite apparatus according to the embodiment.

### DESCRIPTION OF EMBODIMENTS

Hereinafter, an embodiment of the disclosure will be described with reference to the drawings.

### Overall Configuration of FIB-SEM Composite Apparatus 100

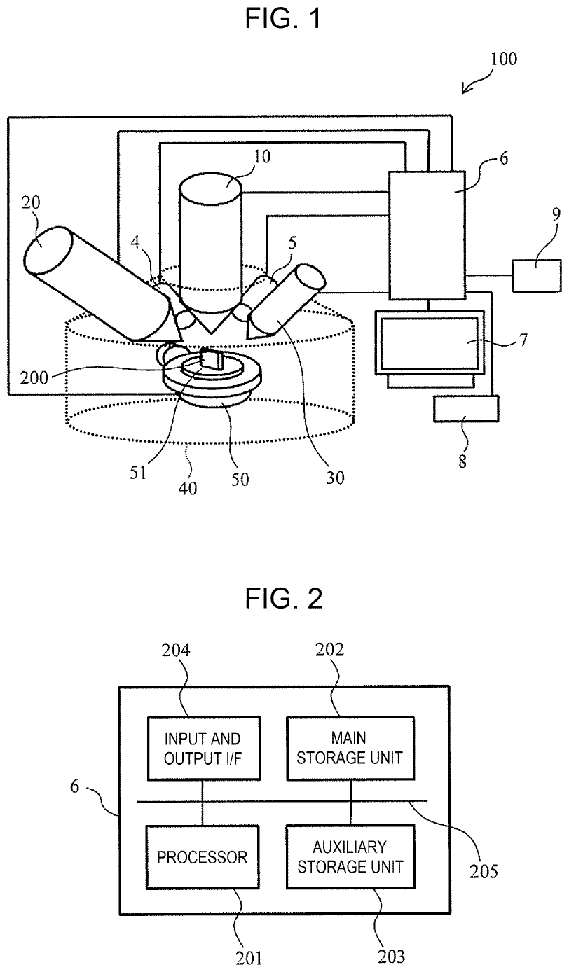

FIG. 1 is a diagram illustrating an overall configuration of the FIB-SEM composite apparatus 100. The FIB-SEM composite apparatus 100 is a charged particle beam apparatus that generates an observation image of a sample by irradiating the sample with a charged particle beam (electron beam, focused ion beam, or gas ion beam). In FIG. 1, the FIB-SEM composite apparatus 100 includes an electron beam column (SEM column) 10 in which an optical system that irradiates a sample with an electron beam is disposed, a focused ion beam column (FIB column) 20 in which an optical system that irradiates the sample with a focused ion beam is disposed, a gas ion beam column 30, a secondary electron detector 4, and a gas gun 5. The FIB-SEM composite apparatus 100 further includes a control device 6 (control unit) that is a computer system including a CPU, a memory, and the like, a display device 7 (display unit) such as a liquid crystal display device, an input device 8 such as a keyboard and a mouse, and a storage device 9 such as a hard disk drive (HDD) and a solid state drive (SSD). In addition, the FIB-SEM composite apparatus 100 includes a sample stage 50 and a sample table (sample holder) 51 disposed on the sample stage 50. Some or all of components of the FIB-SEM composite apparatus 100 are disposed in a vacuum chamber 40, and a pressure in the vacuum chamber 40 is reduced to a predetermined degree of vacuum.

The sample stage 50 movably supports the sample table 51, and a sample 200 is placed on the sample table 51. The sample stage 50 includes a moving mechanism that can displace the sample table 51 in five axes. The above-described moving mechanism can be implemented by various actuators such as a piezo element and a stepping motor. The sample stage 50 moves the sample 200 to a plurality of irradiation positions of the electron beam, the focused ion beam, and the gas ion beam by displacing the sample table 51 in five axes. At these irradiation positions, a surface (cross section) of the sample 200 is irradiated with the electron beam, the focused ion beam, and the gas ion beam, and processing (machining, observation) on the sample 200 is executed.

Although not illustrated, the SEM column 10 includes an electron source that emits electrons and an electron optical system that shapes the electrons emitted from the electron source into a beam and scans the beam. When the sample 200 is irradiated with the electron beam, which is the charged particle beam, emitted from the SEM column 10, secondary electrons are generated from the sample 200. The generated secondary electrons are detected by a secondary electron detector (not illustrated) inside the column or the secondary electron detector 4 outside the column to acquire an observation image of the sample 200. The electron optical system includes, for example, a condenser lens that focuses the electron beam, an aperture that narrows the electron beam, an aligner that adjusts an optical axis of the electron beam, an objective lens that focuses the electron beam on the sample 200, and a deflector that scans the electron beam on the sample 200.

Although not illustrated, the FIB column 20 includes an ion source that generates ions and an ion optical system that shapes the ions emitted from the ion source into a focused ion beam and scans the focused ion beam. When the sample 200 is irradiated with the focused ion beam, which is the charged particle beam, emitted from the FIB column 20, secondary charged particles, such as secondary ions and secondary electrons, are generated from the sample 200. The secondary charged particles are detected by the secondary electron detector 4 to acquire an observation image of the sample 200. Further, the FIB column 20 increases an irradiation amount of the focused ion beam, thereby etching (cross-sectioning) the sample 200 in an irradiation range. The ion optical system includes a known configuration, and includes, for example, a condenser lens that focuses the focused ion beam, an aperture that narrows the focused ion beam, an aligner that adjusts an optical axis of the focused ion beam, an objective lens that focuses the focused ion beam on the sample, and a deflector that scans the focused ion beam on the sample 200.

Although not illustrated, the gas ion beam column 30 includes an ion source that generates ions, which are, for example, argon ions, a condenser lens that focuses an ion beam emitted from the ion source, blanking, an aperture that narrows the ion beam, and an objective lens that focuses the ion beam.

The gas gun 5 supplies a predetermined gas, such as an etching gas, to the sample 200. By irradiating the sample 200 with the electron beam, the focused ion beam, or the gas ion beam while supplying the etching gas from the gas gun 5, a speed at which the sample is etched by irradiating the sample with the beam can be increased. Further, by irradiating the sample 200 with the electron beam, the focused ion beam, or the gas ion beam while supplying a compound gas from the gas gun 5, local deposition for a gas component can be performed in a vicinity of a beam irradiation region. Although an example in which the gas is supplied for the deposition has been described here, the deposition can also be performed by irradiating a sample with the electron beam, the focused ion beam, or the gas ion beam in a contamination environment without using gas.

### Hardware Configuration of Control Device 6

FIG. 2 is a block diagram illustrating the hardware structure of the control device 6. The control device 6 includes a processor 201, a main storage unit 202, an auxiliary storage unit 203, an input and output I/F 204, and a bus 205 that communicably connects the modules. The processor 201 is, for example, a central processing unit (CPU), a digital signal processor (DSP), or an application specific integrated circuit (ASIC). The processor 201 loads an application program and an adjustment recipe stored in the storage device 9 in an executable manner into a work area of the main storage unit 202. The main storage unit 202 stores the application program and the adjustment recipe executed by the processor 201, and data processed by this processor, and the like. The main storage unit 202 is a flash memory, a random access memory (RAM), or the like. The auxiliary storage unit 203 stores a boot program of the FIB-SEM composite apparatus 100, and the like, and is, for example, a read only memory (ROM).

The input and output I/F 204 is communicably connected to the SEM column 10, the FIB column 20, the gas ion beam column 30, the secondary electron detector 4, the gas gun 5, and the sample stage 50 described above. Further, the input and output I/F 204 is communicably connected to the display device 7 that displays an observation image of the sample 200 and the like, the input device 8 that acquires an input instruction from an operator, and the storage device 9 that stores an application program and an adjustment recipe. The processor 201 executes the application program, the adjustment recipe, and the like stored in the storage device 9 and executes various arithmetic processes, whereby the control device 6 controls the components of the FIB-SEM composite apparatus 100.

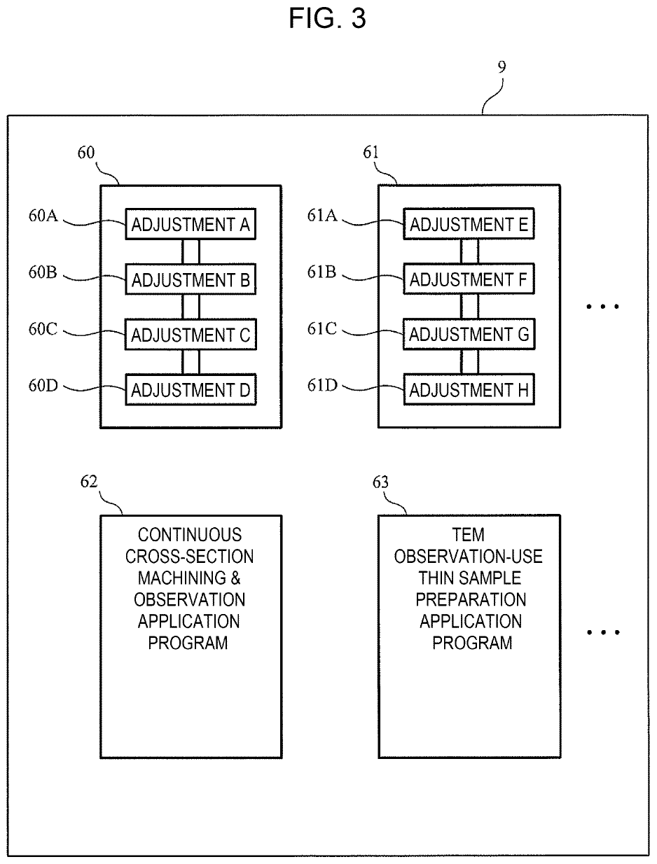

FIG. 3 is a diagram illustrating a plurality of adjustment recipes 60 and 61 and application programs 62 and 63 stored in the storage device 9. The application program is a program for executing processing (machining, observation) on a sample. The adjustment recipe is a program for executing an adjustment of an apparatus condition (optical system condition, gas supply system condition) of the FIB-SEM composite apparatus 100. In an example in FIG. 3, the plurality of adjustment recipes 60 and 61 and the plurality of application programs 62 and 63 are stored in the storage device 9, but the adjustment recipes 60 and 61 and the application programs 62 and 63 may be stored in different storage devices. By executing the application program, the control device 6 causes the processing (machining, observation) on the sample to be executed. Further, by executing the adjustment recipe, the control device 6 causes the adjustment of the apparatus condition to be executed.

### Adjustment Recipes 60 and 61

The plurality of adjustment recipes 60 and 61 are stored in the storage device 9. The adjustment recipes 60 and 61 are each a program for executing the adjustment of the apparatus condition of the FIB-SEM composite apparatus 100. The apparatus condition includes a condition of the optical system in the SEM column 10 and a condition of the gas supply system of the gas supplied from the gas gun 5. The adjustment recipe 60 includes a plurality of adjustment items 60A to 60D with a defined execution order, and when the control device 6 executes the adjustment recipe 60, the adjustment items 61A, 60B, 60C, and 60D are executed in this execution order. Further, the adjustment recipe 61 includes a plurality of adjustment items 61A to 61D with a defined execution order, and when the control device 6 executes the adjustment recipe 61, the adjustment items 61A, 61B, 61C, and 61D are executed in this execution order.

### Examples of Adjustment Items

Here, specific examples of the adjustment items 60A to 60D and 61A to 61D will be described.

The adjustment items include, for example, power-on (startup) of the FIB-SEM composite apparatus 100, power-on (startup) of the FIB column 20, power-on (startup) of the SEM column 10, flashing of the SEM column 10, degas, an axis adjustment of the charged particle beam (electron beam, focused ion beam), a contrast adjustment, a focus adjustment, a stigma adjustment, and Depo Rate coefficient setting.

The storage device 9 stores a continuous cross-section observation application program 62 and a TEM observation-use thin sample preparation application program 63. The application program stored in the storage device 9 is not limited to the application programs 62 and 63.

### Continuous Cross-Section Observation Application Program 62

The continuous cross-section observation application program 62 is an application program that is used for 3D structure analysis of a sample and alternately and continuously executes equally spaced slice machining performed by FIB and observation for the machined surface performed by SEM.

### TEM Observation-Use Thin Sample Preparation Application Program 63

This is an application program for preparing a thin sample for observation performed by a transmission electron microscope (TEM). By executing the application program 63, the thin sample for TEM observation is prepared by performing a finishing machining of reducing a film thickness such that the thin sample includes only a desired observation target (for example, one device structure of interest).

### Adjustment Recipe Display Screen 70

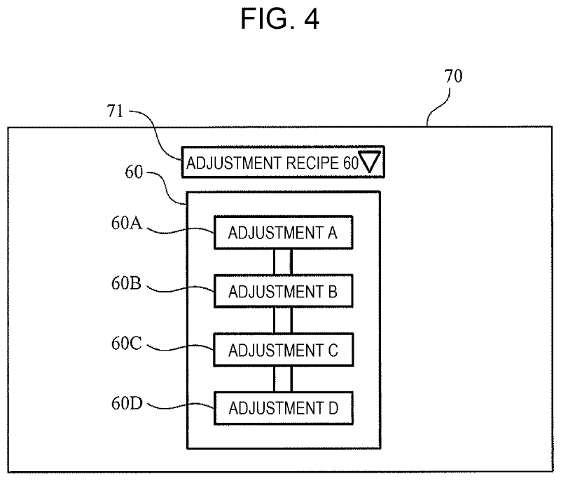

FIG. 4 is a diagram illustrating an adjustment recipe display screen displayed on the display device 7. The adjustment recipe display screen 70 is a screen that displays a selected adjustment recipe. A user can customize the adjustment items on the adjustment recipe display screen 70. The customization of adjustment items includes rearrangement of adjustment items, addition of an adjustment item, deletion of an adjustment item, change of a parameter in an adjustment item, and the like.

The adjustment recipe display screen 70 includes a selection box 71 for selecting an adjustment recipe. The user can select the adjustment recipe using the selection box 71. In an example in FIG. 4, the adjustment recipe 60 is selected in the selection box 71. Therefore, on the adjustment recipe display screen 70, the adjustment items 60A to 60D of the adjustment recipe 60 are displayed in this order.

### Customization of Adjustment Recipe

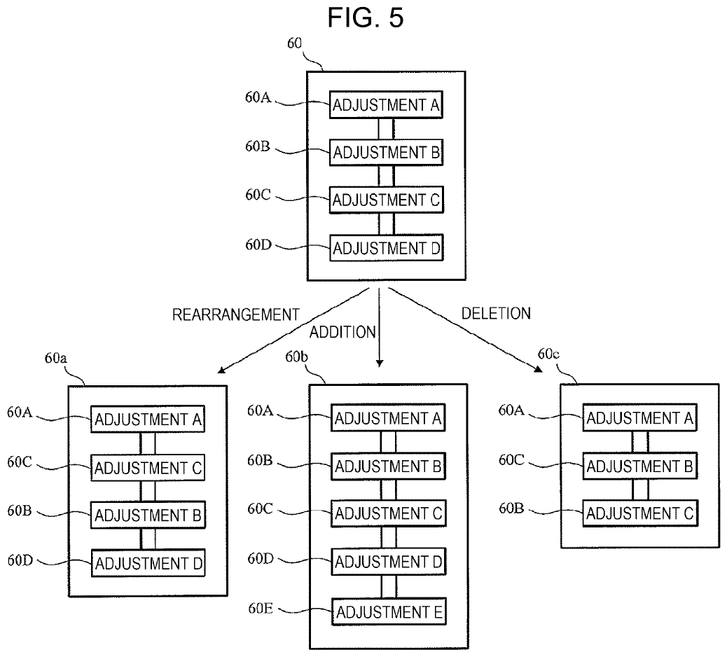

In the FIB-SEM composite apparatus 100, the adjustment recipe can be customized automatically or manually. FIG. 5 is a diagram illustrating a method of customizing the adjustment recipe.

Here, a method of manually customizing the adjustment recipe according to a user instruction will be described. First, the user selects an adjustment recipe from a plurality of adjustment recipes in the selection box 71 (see FIG. 4). For example, when the adjustment recipe 60 is selected, the adjustment items 60A to 60D of the adjustment recipe 60 are displayed on the display device 7 in this order.

When switching the order of the adjustment items 60B and 60C of the adjustment recipe 60, for example, the user moves the adjustment item 60B below the adjustment item 60C. Accordingly, the adjustment recipe 60 can be customized to an adjustment recipe 60a in which the adjustment items 61A, 60C, 60B, and 60D are executed in this order.

When adding an adjustment item 60E to the adjustment recipe 60, for example, the user drops the adjustment item 60E dragged from another window onto the adjustment recipe 60 displayed on the display device 7. Accordingly, the adjustment recipe 60 can be customized to an adjustment recipe 60b in which the adjustment items 61A, 60B, 60C, 60D, and 60E are executed in this order. Here, the adjustment item 60E is added to the end of the adjustment recipe 60b, but the adjustment item 60E may be added to a dragged position.

When deleting the adjustment item 60D of the adjustment recipe 60, for example, the user selects and deletes the adjustment item 60D of the adjustment recipe 60. Accordingly, the adjustment recipe 60 can be customized to an adjustment recipe 60c in which the adjustment items 61A, 60B, and 60C are executed in this order.

### Method for Adjusting FIB-SEM Composite Apparatus 100

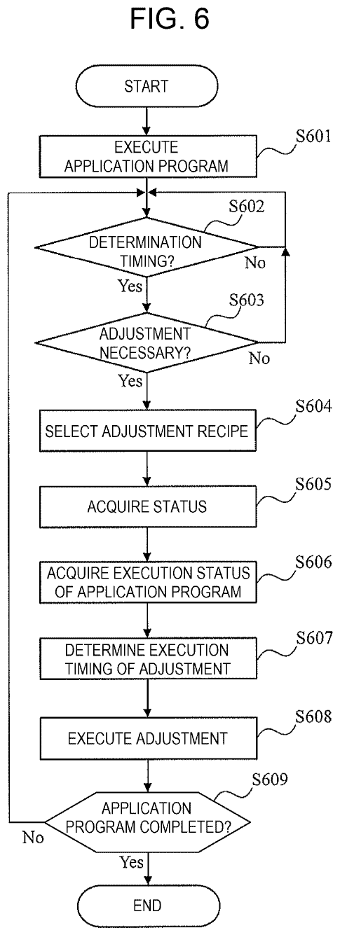

FIG. 6 is a flowchart illustrating a method for adjusting the FIB-SEM composite apparatus 100.

First, the control device 6 executes the application program (for example, the continuous cross-section observation application program 62, the TEM observation-use thin sample preparation application program 63) stored in the storage device 9 (step S601). During the execution of the application program, the control device 6 determines whether a determination timing has come (step S602), and if it is determined that the determination timing has come (step S602: Yes), the control device 6 determines whether an adjustment is necessary based on an implementation determination criterion (step S603). In the present embodiment, the control device 6 determines whether execution of the adjustment is necessary based on an adjustment history of the FIB-SEM composite apparatus 100 or an observation image serving as the implementation determination criterion. If it is determined that it is not the determination timing (step S602: No) and if it is determined that the adjustment is not necessary (step S603: No), it is determined again after a predetermined time has passed whether the determination timing has come (step S602).

If it is determined that the adjustment is necessary (step S603: Yes), the control device 6 selects an adjustment recipe to be executed from a plurality of adjustment recipes based on the implementation determination criterion (step S604). For example, when the adjustment is periodically executed based on the adjustment history, an adjustment recipe including an adjustment item that needs to be periodically executed is selected, and when the adjustment is executed based on a change in the observation image, an adjustment recipe related to a brightness adjustment is selected if a change in brightness is observed from the observation image. The control device 6 may automatically customize the selected adjustment recipe based on the implementation determination criterion (for example, the adjustment history related to the adjustment executed in the FIB-SEM composite apparatus 100 or the observation image).

Next, the control device 6 acquires a status (for example, during machining, during observation, during standby, or the like) of the FIB-SEM composite apparatus 100 (step S605). Further, the control device 6 acquires an execution status of the executed application program (step S606).

Then, the control device 6 determines a timing, at which the adjustment is executed, based on the status of the FIB-SEM composite apparatus 100 acquired in step S605 and the execution status of the application program acquired in step S606 (step S607). Then, the control device 6 executes the adjustment by executing the selected adjustment recipe at the determined timing (step S608). The control device 6 sequentially executes the adjustment items in the adjustment recipe in an order defined in the adjustment recipe.

Then, the control device 6 determines whether the application program is completed (step S609), and if the application program is completed (step S609: Yes), the control device 6 ends the present flowchart. If the application program is not completed (step S609: No), it is determined again whether the determination timing has come (step S602).

### Determination Timing

Next, specific examples of the determination timing in step S602 in FIG. 6 will be described.

The determination timing in step S602 in FIG. 6 may be
every specified time during machining and/or observation of the sample,
every range pitch during machining and/or observation of the sample,
every predetermined time unit (for example, several seconds),
each time the sample is transferred,
every specified position (for example, specified machining position, specified observation position), or
a time when a predetermined GUI button displayed on the display device 7 is selected.

### Implementation Determination Criterion

Next, specific examples of the implementation determination criterion in step S604 in FIG. 6 will be described.

The implementation determination criterion may be
a predetermined time,
the number of executions of a recipe for executing machining and/or observation of the sample,
a specified time during machining and/or observation of the sample,
every range pitch during machining and/or observation of the sample,
every predetermined time unit (for example, several seconds),
the number of times the sample is transferred, or
every specified position (for example, a specified machining position, a specified observation position).

Further, the charged particle beam apparatus 1
may determine to execute the adjustment based on a comparison between a previous observation image and a current observation image,
may determine to execute the adjustment based on a comparison between a correct image and the current observation image,
may determine to execute the adjustment based on a shape or an area of a hole formed by hole machining of the FIB,
may determine to execute the adjustment based on a film thickness deposited by Depo,
may determine to execute the adjustment when the machining of the sample fails,
may determine to execute the adjustment based on a deviation between a mark position of a created Drift correction and a machining position after the sample is machined,
may observe a mark of the created drift correction with a parameter of a charged particle beam used in machining and determine to execute the adjustment when an amount of deviation exceeds a threshold value,
may determine a feature of the observation image by AI and determine to execute the adjustment based on a determination result obtained by AI, or
may determine to execute the adjustment based on an edge amount, an edge vector amount, and blobs between the observation image and a normal image.

The above-described observation image may be an observation image of a sample machined by irradiating the sample with the electron beam, or may be an observation image of a sample machined by irradiating the sample with the focused ion beam.

### Effects of Embodiment

In the present embodiment, based on the adjustment history of the FIB-SEM composite apparatus 100 or the observation image, it is determined whether the execution of the adjustment is necessary and an adjustment recipe to be executed is selected from a plurality of adjustment recipes. Further, in the present embodiment, a timing, at which the adjustment is executed during the execution of the application program, is determined based on the status of the FIB-SEM composite apparatus 100 and the execution status of the application program. Accordingly, it is possible to appropriately select an adjustment to be executed and execute the selected adjustment at an appropriate timing.

It is possible to improve the efficiency of a work in the FIB-SEM composite apparatus 100 by the above-described automatic adjustment function.

In addition, since the adjustment is appropriately executed by the above-described automatic adjustment function, it is possible to equalize the machining of the sample and the observation image.

In the present embodiment, the adjustment recipe selected based on the adjustment history of the FIB-SEM composite apparatus 100 or the observation image can be automatically customized. Accordingly, an appropriate adjustment recipe based on the adjustment history or the observation image can be created. Further, the user can manually customize the adjustment recipe.

Although the disclosure has been specifically described based on the above-described embodiment, the disclosure is not limited to the above-described embodiment, and various modifications can be made without departing from the gist of the invention.

For example, in the above-described embodiment, the FIB-SEM composite apparatus including the SEM column 10 and the FIB column 20 has been described as an example of the charged particle beam apparatus according to the disclosure, but the charged particle beam apparatus according to the disclosure may be an SEM apparatus including only the SEM column or an FIB apparatus including only the FIB column 20.

### REFERENCE SIGNS LIST

100: FIB-SEM composite apparatus
10: SEM column
20: FIB column
30: gas ion beam column
4: secondary electron detector
5: gas gun
6: control device
7: display device
8: input device
9: storage device
40: vacuum chamber
50: sample stage
51: sample table
200: sample

1.-12. (canceled)

13. A charged particle beam apparatus for generating an observation image of a sample by irradiating the sample with a charged particle beam, the charged particle beam apparatus comprising:
a storage unit configured to store a program for executing processing on the sample and a plurality of adjustment recipes for executing an adjustment of an apparatus condition of the charged particle beam apparatus; and
a control unit configured to cause the processing on the sample to be executed by executing the program stored in the storage unit and to cause the adjustment of the apparatus condition to be executed by executing the adjustment recipe stored in the storage unit, wherein
the control unit
selects the adjustment recipe to be executed from the plurality of adjustment recipes stored in the storage unit based on an adjustment history of the charged particle beam apparatus or the observation image, and
determines a timing, at which the adjustment is executed during execution of the program, based on a status of the charged particle beam apparatus and an execution status of the program to execute the selected adjustment recipe at the determined timing.

14. The charged particle beam apparatus according to claim 13, wherein
the adjustment recipe includes one or a plurality of adjustment items with a defined execution order, and
the control unit changes the execution order of the one or plurality of adjustment items of the adjustment recipe selected based on the adjustment history of the charged particle beam apparatus or the observation image, adds the adjustment item, deletes the adjustment item, or changes a parameter of the adjustment item.

15. The charged particle beam apparatus according to claim 13, wherein
the adjustment recipe includes one or a plurality of adjustment items with a defined execution order, and
the control unit changes the execution order of the one or plurality of adjustment items of the adjustment recipe, adds the adjustment item, deletes the adjustment item, or changes a parameter of the adjustment item according to a user instruction.

16. The charged particle beam apparatus according to claim 13, further comprising:
at least one of an optical system configured to irradiate the sample with the charged particle beam or a gas supply system configured to supply a gas to the sample irradiated with the charged particle beam, wherein
the apparatus condition includes at least one of a condition of the optical system or a condition of the gas supply system.

17. The charged particle beam apparatus according to claim 13, comprising:
at least one of an electron beam column configured to irradiate the sample with an electron beam or a focused ion beam column configured to irradiate the sample with a focused ion beam.

18. The charged particle beam apparatus according to claim 13, wherein
the charged particle beam apparatus is an apparatus configured to machine the sample by irradiating the sample with an electron beam and to generate the observation image of the machined sample, and
the control unit selects the adjustment recipe to be executed from the plurality of adjustment recipes stored in the storage unit based on the observation image of the sample machined by the electron beam.

19. The charged particle beam apparatus according to claim 13, wherein
the charged particle beam apparatus is an apparatus configured to machine the sample by irradiating the sample with a focused ion beam and to generate the observation image of the sample, and
the control unit selects the adjustment recipe to be executed from the plurality of adjustment recipes stored in the storage unit based on the observation image of the sample machined by the focused ion beam.

20. The charged particle beam apparatus according to claim 13, wherein
the program includes a program for continuously executing machining of the sample and observation of a machined surface of the sample, and
the control unit selects the adjustment recipe to be executed from the plurality of adjustment recipes stored in the storage unit based on a change in the observation image of the machined surface.

21. The charged particle beam apparatus according to claim 13, wherein
the control unit determines whether the adjustment is necessary
at every specified time during machining or observation of the sample,
at every specified range pitch during machining of the sample,
at every specified time,
each time the sample is transferred,
at every specified position of the sample, or
when a GUI button displayed on a display unit is selected.

22. A method for adjusting a charged particle beam apparatus for generating an observation image of a sample by irradiating the sample with a charged particle beam, the method comprising:
executing a program for executing processing on the sample to execute the processing on the sample;
selecting the adjustment recipe to be executed from a plurality of adjustment recipes for executing an adjustment of the apparatus condition based on an adjustment history of the charged particle beam apparatus or the observation image; and
determining a timing, at which the adjustment is executed during execution of the program, based on a status of the charged particle beam apparatus and an execution status of the program to execute the selected adjustment recipe at the determined timing.

23. The method for adjusting a charged particle beam apparatus according to claim 22, wherein
the adjustment recipe includes one or a plurality of adjustment items with a defined execution order, and
the method further comprises:
changing the execution order of the one or plurality of adjustment items of the adjustment recipe selected based on the adjustment history of the charged particle beam apparatus or the observation image, adding the adjustment item, deleting the adjustment item, or changing a parameter of the adjustment item.

24. The method for adjusting a charged particle beam apparatus according to claim 22, wherein
the adjustment recipe includes one or a plurality of adjustment items with a defined execution order, and
the method further comprises:
changing the execution order of the one or plurality of adjustment items of the adjustment recipe, adding the adjustment item, deleting the adjustment item, or changing a parameter of the adjustment item according to a user instruction.
